(19) United States
(12) Patent Application Publication
(10) Pub. No.: US 2023/0017764 A1
(43) Pub. Date: Jan. 19, 2023

(54) SEMICONDUCTOR STRUCTURE AND METHOD FOR PREPARING SEMICONDUCTOR STRUCTURE

(71) Applicants: CHANGXIN MEMORY TECHNOLOGIES, INC., Hefei City (CN); BEIJING SUPERSTRING ACADEMY OF MEMORY TECHNOLOGY, Beijing (CN)

(72) Inventors: Jie LUO, Hefei City (CN); Deyuan XIAO, Hefei City (CN)

(73) Assignees: CHANGXIN MEMORY TECHNOLOGIES, INC., Hefei City (CN); BEIJING SUPERSTRING ACADEMY OF MEMORY TECHNOLOGY, Beijing (CN)

(21) Appl. No.: 17/947,682

(22) Filed: Sep. 19, 2022

Related U.S. Application Data
(63) Continuation of application No. PCT/CN2022/100696, filed on Jun. 23, 2022.

(30) Foreign Application Priority Data
Jan. 18, 2022 (CN) 202210054708.X

(51) Int. Cl. H01L 27/108

(52) U.S. Cl. CPC H01L 27/10826; H01L 27/10879

(57) ABSTRACT

A semiconductor structure and a method for preparing a semiconductor structure are provided. The semiconductor structure includes a substrate. A first active area, a second active area and an isolation structure are arranged on the substrate. The first active area and the second active area are isolated from one another by the isolation structure. The first active area includes a first doped region and a second doped region. The second active area includes a third doped region and a fourth doped region. The semiconductor structure further includes a gate structure. The gate structure is arranged above the second doped region and the third doped region, and the gate structure is connected to the second doped region and the third doped region.

### CROSS-REFERENCE TO RELATED APPLICATIONS

This application is a continuation application of International Patent Application No. PCT/CN2022/100696, filed on Jun. 23, 2022, which claims priority to Chinese Patent Application No. 202210054708.X, filed on Jan. 18, 2022. The disclosures of these applications are hereby incorporated by reference in their entirety.

### BACKGROUND

The Dynamic Random Access Memory (DRAM) in the related art includes a memory cell and a peripheral control device. With the progress of semiconductor manufacturing technology, the critical dimension defined in the design specifications for semiconductor components is getting smaller and smaller, which increases the manufacturing difficulty of the peripheral control device.

### SUMMARY

The disclosure relates to, but is not limited to, a semiconductor structure and a method for preparing a semiconductor structure.

According to a first aspect, embodiments of the disclosure provide a semiconductor structure including a substrate.

A first active area, a second active area and an isolation structure are arranged on the substrate. The first active area and the second active area are isolated from one another by the isolation structure.

The first active area includes a first doped region and a second doped region. The second active area includes a third doped region and a fourth doped region.

The semiconductor structure further includes a gate structure. The gate structure is arranged above the second doped region and the third doped region, and the gate structure is connected to the second doped region and the third doped region.

According to a second aspect, the embodiments of the disclosure provide a method for preparing a semiconductor structure, which includes the following operations.

A substrate is provided.

A first active area, a second active area and an isolation structure are formed on the substrate, in which the first active area and the second active area are isolated from one another by the isolation structure.

A first doped region is formed at one of two ends of the rust active area and a second doped region is formed at the other of the two ends of the first active area. A third doped region is formed at one of two ends of the second active area and a fourth doped region is formed at the other of the two ends of the second active area.

A gate structure is formed above the second doped region and the third doped region, in which the gate structure is connected to the second doped region and the third doped region.

### BRIEF DESCRIPTION OF THE DRAWINGS

FIG. 1 is a schematic diagram of a semiconductor structure according to an embodiment of the disclosure.

FIG. 2 is a schematic diagram of another semiconductor structure according to an embodiment of the disclosure.

FIG. 3 is a schematic diagram of yet another semiconductor structure according to an embodiment of the disclosure.

FIG. 4 is a circuit diagram of a semiconductor structure according to an embodiment of the disclosure.

FIG. 5 is a flowchart of a method for preparing a semiconductor structure according to an embodiment of the disclosure.

FIG. 6A is a schematic diagram I of a process of preparing a semiconductor structure according to an embodiment of the disclosure.

FIG. 6B is a schematic diagram II of a process of preparing a semiconductor structure according to an embodiment of the disclosure.

FIG. 7A is a schematic diagram III of a process of preparing a semiconductor structure according to an embodiment of the disclosure.

FIG. 7B is a schematic diagram IV of a process of preparing a semiconductor structure according to an embodiment of the disclosure.

FIG. 8A is a schematic diagram V of a process of preparing a semiconductor structure according to an embodiment of the disclosure.

FIG. 8B is a schematic diagram VI of a process of preparing a semiconductor structure according to an embodiment of the disclosure.

FIG. 9A is a schematic diagram VII of a process of preparing a semiconductor structure according to an embodiment of the disclosure.

FIG. 9B is a schematic diagram VIII of a process of preparing a semiconductor structure according to an embodiment of the disclosure.

FIG. 10A is a schematic diagram IX of a process of preparing a semiconductor structure according to an embodiment of the disclosure.

FIG. 10B is a schematic diagram X of a process of preparing a semiconductor structure according to an embodiment of the disclosure.

FIG. 11A is a schematic diagram XI of a process of preparing a semiconductor structure according to an embodiment of the disclosure.

FIG. 11B is a schematic diagram XII of a process of preparing a semiconductor structure according to an embodiment of the disclosure.

FIG. 12A is a schematic front view of another semiconductor structure according to an embodiment of the disclosure.

FIG. 12B is a schematic top view of another semiconductor structure according to an embodiment of the disclosure.

FIG. 13 is a schematic diagram of an electronic device according to an embodiment of the disclosure.

### DETAILED DESCRIPTION

Technical solutions in the embodiments of the disclosure are clearly and completely described below in combination with the drawings in the embodiments of the disclosure. It is to be understood that the specific embodiments described herein are merely illustrative of the disclosure and are not intended to limit the disclosure. In addition, it is also to be noted that for ease of description, only the parts related to the relevant disclosure are shown in the drawings.

Unless otherwise defined, all technological and scientific terms used in the disclosure have meanings the same as those usually understood by those skilled in the art of the disclosure. The terms used in the disclosure are only adopted to describe the embodiments of the disclosure and not intended to limit the disclosure.

“Some embodiments” involved in the following descriptions describes a subset of all possible embodiments. However, it can be understood that “some embodiments” may be the same subset or different subsets of all the possible embodiments, and may be combined with each other without conflicts.

It is to be pointed out that terms “first/second/third” involved in the embodiments of the disclosure are only for distinguishing similar objects and do not represent a specific sequence of the objects. It can be understood that “first/second/third” may be interchanged to specific sequences or orders if allowed to implement the embodiments of the disclosure described herein in sequences except the illustrated or described ones.

English abbreviations involved in the disclosure are explained as follows.

MOS (Metal-Oxide-Semiconductor Field-Effect Transistor): Metal-Oxide Semiconductor Field Effect Transistor.

NMOS: N-type MOS transistor, a semiconductor in which electronic conduction predominates.

PMOS: P-type MOS transistor, a semiconductor in which hole conduction predominates.

FinFET (Finfield Effect Transistor): Fin Field Effect Transistor.

The DRAM in the related art includes a memory cell and a peripheral control device. With the progress of semiconductor manufacturing technology, the critical dimension defined in the design specifications for semiconductor components is getting smaller and smaller, which increases the manufacturing difficulty of the peripheral control device.

The embodiments of the disclosure provide a semiconductor structure. The semiconductor structure includes a substrate. A first active area, a second active area and an isolation structure are arranged on the substrate. Herein, the first active area and the second active area are isolated from one another by the isolation structure. The first active area includes a first doped region and a second doped region. The second active area includes a third doped region and a fourth doped region. The semiconductor structure further includes a gate structure. The gate structure is arranged above the second doped region and the third doped region, and the gate structure is connected to the second doped region and the third doped region. Thus, the gate structure is arranged on the second doped region in the first active area and the third doped region in the second active area, so that the states of the two active areas can be controlled by one gate structure. Accordingly, the device integration is improved, and the electrical property of a semiconductor is improved.

Various embodiments of the present disclosure will now be described in detail in combination with the accompanying drawings.

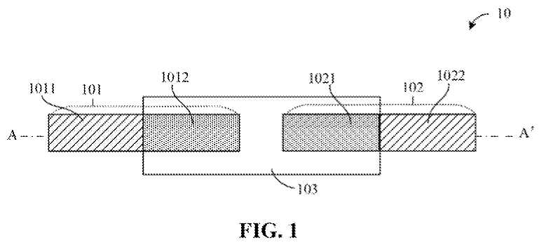

An embodiment of the disclosure refers to FIG. 1, which illustrates a schematic diagram of a semiconductor structure 10 according to an embodiment of the present disclosure. As shown in FIG. 1, the semiconductor structure 10 includes a substrate.

A first active area 101, a second active area 102 and an isolation structure 103 are arranged on the substrate. That is, the isolation structure 103 defines a plurality of active areas on the substrate, the first active area 101 and the second active area 102 are isolated from one another by the isolation structure 103, and an interior of the first active area 101 (or an interior of the second active area 102) is also isolated by the isolation structure 103.

The first active area 101 includes a first doped region 1011 and a second doped region 1012. The second active area 102 includes a third doped region 1021 and a fourth doped region 1022.

The semiconductor structure 10 also includes a gate structure. The gate structure is arranged above the second doped region 1012 and the third doped region 1021, and the gate structure is connected to the second doped region 1012 and the third doped region 1021.

It is to be noted that the isolation structure 103 may be Shallow Trench Isolation (STI).

It is to be noted that FIG. 1 is a top view of the semiconductor structure 10, and a surface of the substrate in FIG. 1 has been covered by the isolation structure or the active areas, thus the substrate is not shown in FIG. 1. It is to be understood that the substrate is arranged below the isolation structure and the active areas.

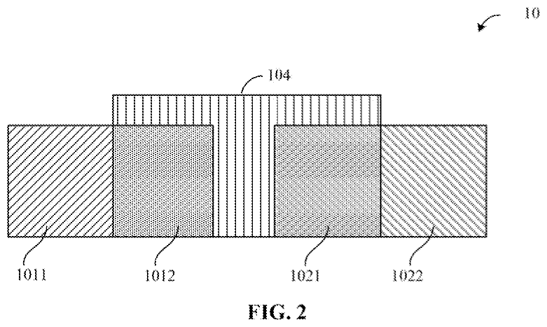

In addition, since the gate structure actually covers the second doped region 1012 and the third doped region 1021, the second doped region 1012 and the third doped region 1021 arm shown in FIG. 1 for a clearer description of the relative positional relationship. With reference to FIG. 2, which illustrates a schematic diagram of another semiconductor structure 10 according to an embodiment of the present disclosure. Particularly, FIG. 2 is a cross-sectional view taken along the direction A-A′ in FIG. 1, and the cross-section is perpendicular to the substrate. As shown in FIG. 2, the gate structure 104 is arranged above the second doped region 1012 and the third doped region 1021.

In some embodiments, the doping type of the second doped region 1012 is the same as the doping type of the third doped region 1021.

It is to be noted that the doping type includes hole doping (P type) and electron doping (N type). Since both the second doped region 1012 and the third doped region 1021 are regions arranged below the gate structure, the same doping type is adopted for the second doped region 1012 and the third doped region 1021.

For example, both the second doped region 1012 and the third doped region 1021 are P-doped, or both the second doped region 1012 and the third doped region 1021 are N-doped.

In some embodiments, the doping type of the first doped region 1011 is contrary to the doping type of the fourth doped region 1022.

For example, the rust doped region 1011 is N-doped, and the fourth doped region is P-doped. Or, the first doped region 1011 is P-doped, and the fourth doped region is N-doped.

In some embodiments, the doping type of the second doped region 1011 is contrary to the doping type of the third doped region 1012.

For example, in case that both the second doped region 1012 and the third doped region 1021 are P-doped, the first doped region 1011 is N-doped. In case that both the second doped region 1012 and the third doped region 1021 are N-doped, the first doped region 1011 is P-doped.

In some embodiments, the doping type of the third doped region 1021 is the same as the doping type of the fourth doped region 1022, and the doping concentration of the third doped region 1021 is different from the doping concentration of the fourth doped region 1022.

For example, in case that both the second doped region 1012 and the third doped region 1021 are P-doped, the fourth doped region 1022 is high-concentration P (P+)-doped. In case that both the second doped region 1012 and the third doped region 1021 are N-doped, the fourth doped region 1022 is high-concentration N (N+)-doped.

In a specific embodiment, the doping type of the first doped region 1011 is N-type doping, each of the doping type of the second doped region 1012, the doping type of the third doped region 1021 and the doping type of the fourth doped region 1022 is P-type doping, and the doping concentration of the fourth doped region 1022 is higher than the doping concentration of the third doped region 1021.

In another specific embodiment, the doping type of the first doped region 1011 is P-type doping, each of the doping type of the second doped region 1012, the doping type of the third doped region 1021 and the doping type of the fourth doped region 1022 is N-type doping, and the doping concentration of the fourth doped region 1022 is higher than the doping concentration of the third doped region 1021.

In some embodiments, as shown in FIG. 1 and FIG. 2, the second doped region 1012 is located at an end of the first active area 101 close to the second active area 102, and the third doped region 1021 is located at an end of the second active area 102 close to the first active area 101.

Thus, it is convenient to form the gate structure 104 on the second doped region 1012 and the third doped region 1021, so that the first active area and the second active area are controlled by one gate structure, which improves the device integration, and improves the electrical property of the semiconductor.

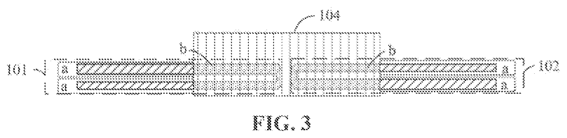

In an application scenario, the semiconductor structure 10 provided by the embodiment of the disclosure may be configured to form a FinFET, and the FinFET can greatly reduce the leakage current, shorten the length of the gate structure of a transistor, and further improve the electrical property. Therefore, some embodiments of the present disclosure refer to FIG. 3, which illustrates a schematic diagram of yet another semiconductor structure according to an embodiment of the present disclosure. As shown in FIG. 3, the first active area 101 and/or the second active area 102 includes a fin structure, and the fin structure is specifically shown at a in FIG. 3.

In some embodiments, the second doped region 1012 includes a first connection region, and the first connection region connects at least two fin structures of the first active area 101 together. In some embodiments, the third doped region 1021 includes a second connection region, and the second connection region connects at least two fin structures of the second active area 102 together.

It is to be noted that at least two fin structures are connected together through the first connection region, so that a channel of the transistor is formed in the first active area 101. At least two fin structures are connected together through the second connection region, so that a channel of the transistor is formed in the second active area 102. Herein, the first connection region and the second connection region are specifically shown at b in FIG. 3.

Here, the specific patterns of the fin structure and the first connection region/second connection region may include various situations, and may be set according to actual needs. For example, the first connection region/second connection region may be located at an end or the middle of the fin structure in the corresponding active area.

It is to be noted that since the gate structure 104 is arranged above the first connection region and the second connection region, the working state of the first connection region and the working state of the second connection region are controlled by the gate structure 104. That is, the gate structure 104 may simultaneously control the working state of the first active area 101 and the working state of the second active area 102.

Detailed description is made below with the first doped region 1011 being N-type doping, the second doped region 1012 and the third doped region 1021 being P-type doping, and the fourth doped region 1022 being P+-type doping as an example.

When the gate structure is in a low potential state, both the first connection region and the second connection region are P-type. At the moment, the first active area forms an NPN channel, which is in a turn-off state, while the second active area forms a P+PP+ channel, which is in a turn-on state. When the gate structure is in a high potential state, the first connection region and the second connection region are inverted to N-type. At the moment, the first active area forms an NNN channel, which is in a turn-on state, while the second active area forms a P+NP+ channel, which is in a turn-off state.

In other words, for the semiconductor structure provided by the embodiment of the present disclosure, by applying different potentials to the gate structure, the first active area can be controlled to form an effective conductive channel or the second active area can be controlled to form an effective conductive channel. Thus, the states of two active areas can be controlled by one gate structure. Accordingly, the device integration is improved, and the electrical property of the semiconductor is improved. In addition, the semiconductor structure provided by the embodiments of the present disclosure may be configured to prepare various electrical devices, such as a NMOS device, a PMOS device, a complementary Metal-Oxide-Semiconductor Field-Effect Transistor (CMOS) device, a Bipolar Junction Transistor (BJT), etc., which is not limited in the embodiments of the disclosure.

The embodiments of the disclosure provide a semiconductor structure. The semiconductor structure includes a substrate. A first active area, a second active area and an isolation structure are arranged on the substrate. Herein, the first active area and the second active area are isolated from one another by the isolation structure. The first active area includes a first doped region and a second doped region. The second active area includes a third doped region and a fourth doped region. The semiconductor structure further includes a gate structure. The gate structure is arranged above the second doped region and the third doped region, and the gate structure is connected to the second doped region and the third doped region. Thus, the gate structure is arranged on the second doped region in the first active area and the third doped region in the second active area, so that the states of two active areas can be controlled by one gate structure. Accordingly, the device integration is improved, and the electrical property of a semiconductor is improved.

In another embodiment of the disclosure, with reference to FIG. 3, the semiconductor structure 10 is further explained with a transistor as an application scenario.

The embodiment of the disclosure provides a semiconductor structure 10. In the semiconductor structure 10, a plurality of active areas are defined on a substrate by an isolation structure, and a pattern with a U-shaped cross section (hereinafter referred to as a U-shaped pattern) is present in each active area. A group of adjacent active areas among the plurality of active areas are referred to as the first active area 101 and the second active area 102.

In terms of doping, the first active area 101 includes a first doped region and a second doped region, and the second active area 102 includes a third doped region and a fourth doped region. The doping type of the second doped region is the same as doping type of the third doped region. In the embodiment of the disclosure, description is made subsequently with the first doped region being N-type doping, the second doped region and the third doped region being P-type doping, and the fourth doped region being P+-type doping as an example, which however does not constitute a relevant limitation to the disclosure.

In terms of structure, as shown in FIG. 3, the first active area 101 includes a first fin structure (at a), a second fin structure (at a) and a first connection region (at b), and one of two end points of the first connection region is connected to an end point of the first fin structure and the other of the two end points of the first connection region is connected to an end point of the second fin structure, so that each of the cross-sectional shape of the first fin structure, the cross-sectional shape of the second fin structure and the cross-sectional shape of the first connection region is U-shaped. In addition, both the first fin structure and the second fin structure are located in the first doped region (N-type doping), and the first connection region is located in the second doped region (P-type doping). In this case, the first active area 101 may be configured to form a junction NMOS, and the first connection region may be used as a conductive channel of the NMOS.

The second active area 102 includes a third fin structure (at a), a fourth fin structure (at a) and a second connection region (at b), and one of two end points of the second connection region is connected to an end point of the third fin structure and the other of the two end points of the second connection region is connected to an end point of the fourth fin structure, so that each of the cross-sectional shape of the third fin structure, the cross-sectional shape of the fourth fin structure and the cross-sectional shape of the second connection region is U-shaped. Both the third fin structure and the fourth fin structure are located in the fourth doped region (P+-type doping), and the second connection region is located in the third doped region (P-type doping). In this case, the second active area 102 may be configured to form a junction-less PMOS, and the second connection region may be used as a conductive channel of the PMOS.

In addition, a gate structure 104 is arranged on an upper side of the first connection region and an upper side of the second connection region, and the gate structure 104 serves as the gate of the NMOS and the gate of the PMOS simultaneously. Specifically, when the gate structure 104 is externally connected to a low potential, the first connection region and the second connection region are in a P-doped state, the channel of the NMOS in the first active area 101 is in an NPN state, that is, a turn-off state, and the channel of the PMOS in the second active area 102 is in a P+PP+ state, that is, a turn-on state. When the gate structure is externally connected to a high potential, the first connection region and the second connection region are inverted into an N-doped state, the channel of the NMOS in the first active area 101 is in an NNN state, that is, a turn-on state, and the channel of the PMOS in the second active area 102 is in a P+NP+ state, that is, a turn-off state.

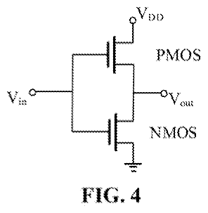

A specific circuit scenario refers to FIG. 4, which illustrates a circuit diagram of a semiconductor structure according to an embodiment of the disclosure. As shown in FIG. 4, the PMOS is externally connected to power supply voltage (V_{DD}), and the NMOS is externally connected to ground voltage (V_{SS}). If a high voltage is applied to the gate, the PMOS is turned of and the NMOS is turned on, and then the ground voltage (V_{SS}) is output. If a low voltage is applied to the gate, the NMOS is turned off and the PMOS is turned on, and then the power supply voltage (V_{DD}) is output. In conclusion, the embodiments of the disclosure provide a semiconductor structure sharing a gate structure, which can increase the integration level of the field effect transistor and improve the electrical property and speed of the device.

The embodiments of the disclosure provide a semiconductor structure. The semiconductor structure includes a substrate. A first active area, a second active area and an isolation structure are arranged on the substrate. Herein, the first active area and the second active area are isolated from one another by the isolation structure. The first active area includes a first doped region and a second doped region. The second active area includes a third doped region and a fourth doped region. The semiconductor structure further includes a gate structure. The gate structure is arranged above the second doped region and the third doped region, and the gate structure is connected to the second doped region and the third doped region. Thus, the gate structure is arranged on the second doped region in the first active area and the third doped region in the second active area, so that the states of two active areas can be controlled by one gate structure. Accordingly, the device integration is improved, and the electrical property of a semiconductor is improved.

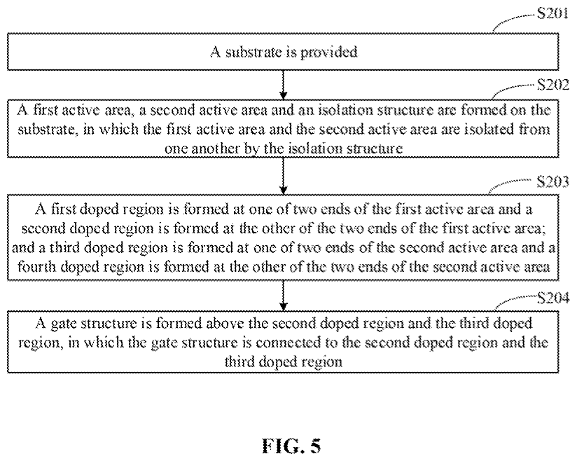

Another embodiment of the disclosure refers to FIG. 5, which illustrates a flowchart of a method for preparing a semiconductor structure according to an embodiment of the disclosure. As shown in FIG. 5, the method may include the following operations.

At S201, a substrate is provided.

It is to be noted that the preparation method provided by the embodiment of the present disclosure is mainly used to prepare the aforementioned semiconductor structure 10.

At S202, a first active area, a second active area and an isolation structure are formed on the substrate, in which the first active area and the second active area are isolated from one another by the isolation structure.

It is to be noted that the isolation structure may be shallow trench isolation. Here, an interior of the first active area or an interior of the second active area is also isolated by the isolation structure.

In some embodiments, the operation that the first active area, the second active area and the isolation structure are formed on the substrate may include the following operations.

A covering layer is formed on the substrate, and a patterned mask is formed on the covering layer.

Pattern transfer processing is performed on the substrate through the patterned mask, and the patterned mask and the covering layer are removed to obtain the first active area and the second active area.

An insulating material is filled between the first active area and the second active area to obtain the isolation structure.

It is to be noted that when the active areas and the isolation structure are prepared, first the substrate is protected by the covering layer, then the patterned mask is formed on the covering layer, and the patterned mask is transferred to the substrate to obtain a substrate with a plurality of trenches. At the moment, the trenches are filled with the insulating material to form the isolation structure, and non-trench areas on a surface of the substrate form the active areas.

In addition, the shape and dimension of the patterned mask need to be designed and determined according to the required active areas. The pattern transfer processing may be a forward pattern transfer processing and may also be reverse pattern transfer processing.

In some embodiments, the operation that the patterned mask is formed on the covering layer may include the following operations.

An initial pattern is formed on the covering layer.

Cutting processing is performed on the initial pattern to obtain a first pattern and a second pattern.

A first dielectric layer is deposited on a sidewall of the first pattern and a sidewall of the second pattern, and the first pattern and the second pattern are removed, in which the first dielectric layer is retained to obtain the patterned mask.

It is to be noted that in the embodiment of the disclosure, the active areas need to appear in pairs. Therefore, after the initial pattern is formed on the covering layer, the initial pattern may be cut into the first pattern and the second pattern. Then a first dielectric layer is deposited on the sidewall of the first pattern, and a second dielectric layer is deposited on the sidewall of the second pattern. Thus, the shape of the first dielectric layer and the shape of the second dielectric layer are patterned masks, and subsequently, the first dielectric layer may assist in forming the first active area, and the second dielectric layer may assist in forming the second active area.

Here, the cross-sectional shape of the active area may be various shapes, such as U-shape, H-shape and V-shape. Taking the cross-sectional shape of the active area being U-shaped as an example below, a specific preparation process is given.

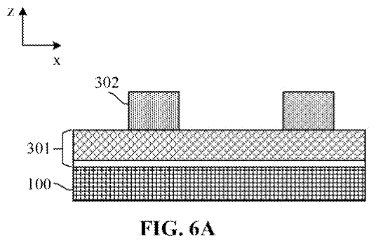

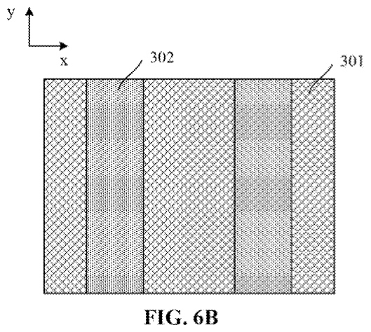

It is to be noted that FIG. 6A to FIG. 11B, which illustrate a schematic diagram of a process of preparing a semiconductor structure according to embodiments of the disclosure. As shown in FIG. 6A to FIG. 11B, the active areas and the isolation structure between the active areas may be prepared by the following operations.

(1) At a first operation, as shown in FIG. 6A and FIG. 6B, a covering layer 301 is formed on a substrate 100, and an initial pattern 302 is formed on the covering layer 301. Herein, the covering layer 301 may include a silicon nitride layer and a silicon oxide layer from top to bottom, and the material of the initial pattern 302 may be polysilicon. The initial pattern 302 includes a plurality of cubic structures spaced apart from each other in the x direction, and different cubic structures are parallel to each other.

Specifically, FIG. 6A is a schematic diagram of the semiconductor structure after the first operation in the x-z direction, and FIG. 6B is a schematic diagram of the semiconductor structure after the first operation in the x-y direction.

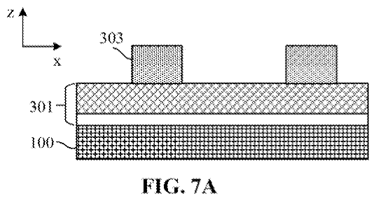

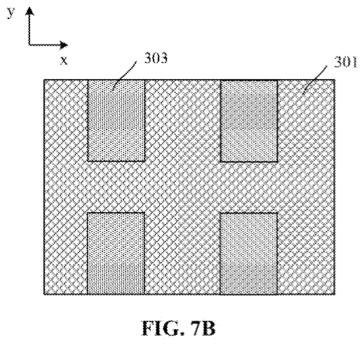

(2) At a second operation, as shown in FIG. 7A and FIG. 7B, a middle pan of the initial pattern 302 is cut in the y direction, in which the shape of the initial pattern 302 in the x-z plane does not change. At the moment, each initial pattern 302 is divided into two symmetrical cubic structures. For convenience of description, the cubic structure obtained after cutting is called a pattern to be processed 303.

Specifically, FIG. 7A is a schematic diagram of the semiconductor structure after the second operation in the x-z direction, and FIG. 7B is a schematic diagram of the semiconductor structure after the second operation in the x-y direction.

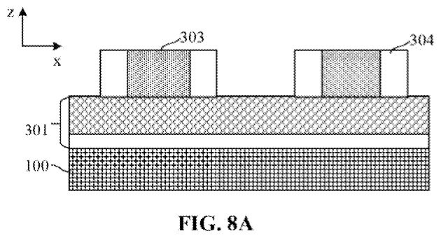

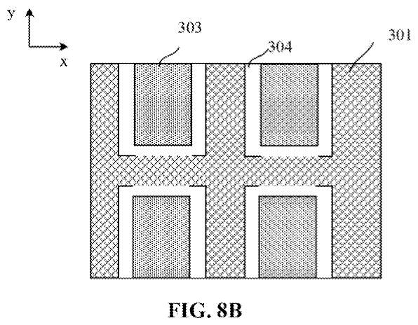

(3) At a third operation, as shown in FIG. NA and FIG. 8B, a first dielectric layer 304 is deposited on a side face of the pattern to be processed 303. The material of the first dielectric layer 304 may be silicon oxide. Thus, the first dielectric layer 304 forms a plurality of patterns with U-shaped cross-section (hereinafter referred to as U-shaped patterns).

Specifically, FIG. 8A is a schematic diagram of the semiconductor structure after the third operation in the x-z direction, and FIG. NB is a schematic diagram of the semiconductor structure after the third operation in the x-y direction.

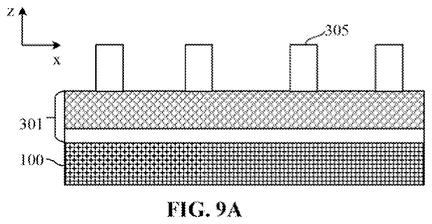

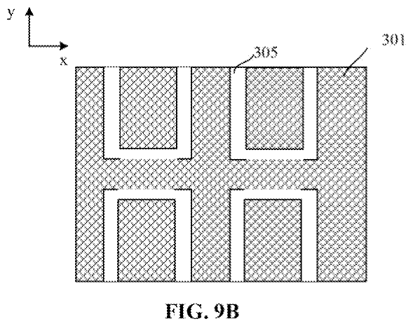

(4) At a fourth operation, as shown in FIG. 9A and FIG. 9B, the pattern to be processed 303 is removed, in which only the first dielectric layer 304 is retained. At the moment, only a plurality of U-shaped patterns are remained on the covering layer 301, that is, the patterned mask 305.

Specifically, FIG. 9A is a schematic diagram of the semiconductor structure after the fourth operation in the x-z direction, and FIG. 9B is a schematic diagram of the semiconductor structure after the fourth operation in the x-y direction.

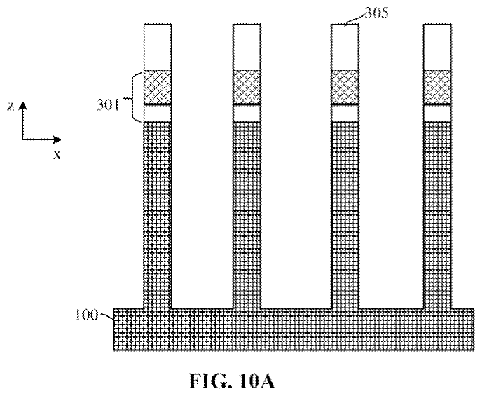

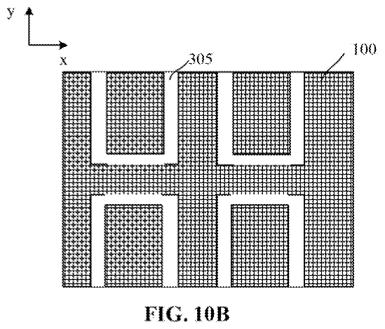

(5) At a fifth operation, as shown in FIG. 10A and FIG. 10B, the part on which the patterned mask 305 is absent is etched downward until a part of the substrate 100 is etched.

Specifically, FIG. 10A is a schematic diagram of the semiconductor structure after the fifth operation in the x-z direction, and FIG. 10B is a schematic diagram of the semiconductor structure after the fifth operation in the x-y direction.

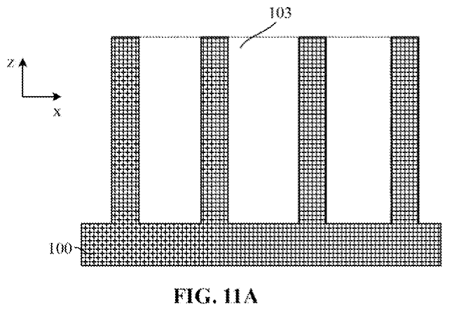

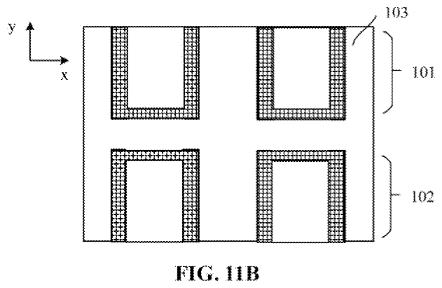

(6) At a sixth operation, as shown in FIG. 11A and FIG. 11B, the patterned mask 305 and a retained part of the covering layer 301 are removed to form a plurality of trenches on the substrate 100. Then, the trenches in the substrate 100 are filled with the insulating material. At the moment, the insulating material filled forms the isolation structure 103, and the part, where no trench is formed, on an upper surface of the substrate 100 forms the active areas. In FIG. 11B, the upper active area may be referred to as the first active area 101, the lower active area as the second active area 102, and the white part is the isolation structure 103.

Specifically, FIG. 11A is a schematic diagram of the semiconductor structure after the sixth operation in the x-z direction, and FIG. 11B is a schematic diagram of the semiconductor structure after the sixth operation in the x-y direction.

Thus, through the above operations, the first active area, the second active area and the doped structure are formed on the substrate.

At S203, a first doped region is formed at one of two ends of the first active area and a second doped region is formed at the other of the two ends of the rust active area; and a third doped region is formed at one of two ends of the second active area and a fourth doped region is formed at the other of the two ends of the second active area.

At S204, a gate structure is formed above the second doped region and the third doped region, in which the gate structure is connected to the second doped region and the third doped region.

It is to be noted that the first doped region is formed at one of two ends of the first active area and the second doped region is formed at the other of the two ends of the first active area, the third doped region is formed at one of two ends of the second active area and the fourth doped region is formed at the other of the two ends of the second active area, and the gate structure also needs to be established above the second doped region and the third doped region. Thus, the gate structure is arranged on the second doped region and the third doped region, so that the states of two active areas can be controlled by one gate structure. Accordingly, the device integration is improved, and the electrical property of a semiconductor is improved.

Since the shape of each of the active areas has many possibilities. Here, the two ends of the first active area refer to: an end of the first active area close to the second active area and an end of the first active area away from the second active area. The two ends of the second active area refer to: an end of the second active area close to the first active area and an end of the first active area away from the second active area.

It is to be noted that the first doped region is formed at the end of the first active area away from the second active area, the second doped region is formed at the end of the first active area close to the second active area, the third doped region is formed at the end of the second active area close to the first active area, and the fourth doped region is formed at the end of the second active area away from the first active area.

It is also to be noted that S303 and S304 have no specific order. That is, the doping operation may be performed before the gate formation operation, or the gate formation operation may be performed before the doping operation, or partial doping operation may be performed, then the gate formation operation is performed, and finally the remaining doping operation is performed.

Two feasible doping methods are given below.

In a specific embodiment, the first doped region and the fourth doped region may be formed first, then the second doped region and the third doped region may be formed, and finally the gate structure may be formed. Therefore, the method may also include the following operations.

A first mask layer is formed on the first active area and the second active area, in which the first mask layer covers part of the first active area and part of the second active area, and the first mask layer exposes the end of the first active area away from the second active area and the end of the second active area away from the first active area.

A first doping process is performed on the end of the first active area away from the second active area to obtain a first doped region. A second doping process is performed on the end of the second active area away from the first active area to obtain a fourth doped region.

The rust mask layer is removed and a second mask layer is formed, in which the second mask layer covers the first doped region and the fourth doped region, and the second mask layer is absent on the end of the first active area close to the second active area and the end of the second active area close to the first active area.

A third doping process is performed on the end of the first active area close to the second active area and the end of the second active area close to the first active area to obtain a second doped region and a third doped region.

The second mask layer is removed, and a gate structure is formed on the second doped region and the third doped region.

It is to be noted that firstly, the part reserved for the second doped region and the third doped region is covered, and the first active area is doped to form the first doped region, and the second active area is doped to form the fourth doped region. It is to be understood that if the doping elements of the first doped region are different from the doping elements of the fourth doped region, the part of the fourth doped region may also be covered when the first active area is formed; and the part of the first doped region may also be covered when the fourth doped region is formed. Secondly, after the first doped region and the fourth doped region are formed, the first mask layer covering the second doped region and the third doped region is removed, the first doped region and fourth doped region are covered by the second mask, and then the first active area is doped to form the second doped region and the second active area is doped to form the third doped region. Here, the second doped region and the third doped region have the same doping process and may be processed together. Finally, the second mask layer is removed, and a gate structure is formed on the second doped region and the third doped region.

In another specific embodiment, the second doped region and the third doped region may be formed first, then the gate structure is formed, and finally the first doped region and the fourth doped region are formed. Therefore, the method may also include the following operations.

A third mask layer is formed on the first active area and the second active area, in which the third mask layer covers part of the first active area and part of the second active area, and the third mask layer exposes the end of the first active area close to the second active area and the end of the second active area close to the first active area.

A third doping process is performed on the end of the first active area close to the second active area and the end of the second active area close to the first active area to obtain a second doped region and a third doped region.

The third mask layer is removed, and a gate structure is formed on the second doped region and the third doped region.

A first doping process is performed on the end of the first active area away from the second active area to obtain a first doped region. A second doping process is performed on the end of the second active area away from the rust active area to obtain a fourth doped region.

It is to be noted that first, the part reserved for the first doped region and the fourth doped region is covered by the third mask layer, and the first active area is doped to form the second doped region and the second active area is doped to form the third doped region. Second, a gate structure is established on the second doped region and the third doped region. Finally, since the gate structure is higher than the second doped region and the third doped region, the gate structure may act as a mask. Therefore, there is no need to form a mask again, the remaining part of the first active area is directly doped to form the first doped region, and the remaining part of the second active area is directly doped to form the fourth doped region.

In some embodiments, the doping type of the first doping process is contrary to the doping type of the third doping process, the doping type of the second doping process is the same as the doping type of the third doping process, and the doping concentration of the second doping process is different from the doping concentration of the third doping process.

Exemplarily, the doping type of the first doped region is N-type doping, each of the doping type of the second doped region, the doping type of the third doped region and the doping type of the fourth doped region is P-type doping, and the doping concentration of the fourth doped region is higher than the doping concentration of the third doped region.

Or, in other embodiments, the doping type of the first doped region is P-type doping, each of the doping type of the second doped region, the doping type of the third doped region and the doping type of the fourth doped region is N-type doping, and the doping concentration of the fourth doped region is higher than the doping concentration of the third doped region.

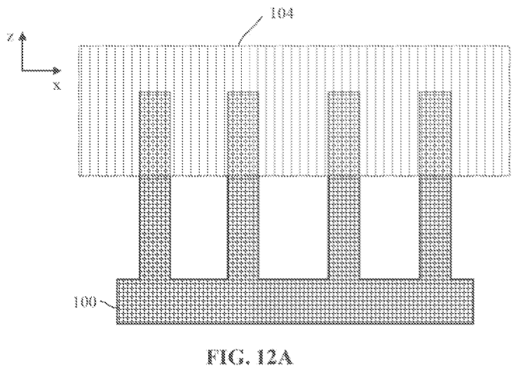

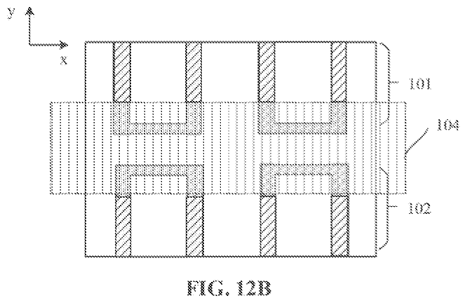

FIG. 12A illustrates an schematic front view of another semiconductor structure according to an embodiment of the disclosure. FIG. 12B illustrates a schematic top view of another semiconductor structure according to an embodiment of the disclosure. For convenience of explanation, the gate structure 104 is shown in a translucent pattern.

As shown in FIG. 12A and FIG. 12B, each of the first active area 101 and the second active area 102 is composed of a plurality of U-shaped patterns. As shown in FIG. 12A, a gate structure 104 is formed above the active areas. As shown in FIG. 12B, the gate structure 104 covers the second doped region in the first active area 101 and the third doped region in the second active area 102.

The embodiments of the disclosure provide a method for preparing the semiconductor structure. The method includes the following operations. A substrate is provided. A first active area, a second active area and an isolation structure are formed on the substrate, in which the first active area and the second active area are isolated from one another by the isolation structure. A first doped region is formed at one of two ends of the first active area and a second doped region is formed at the other of the two ends of the first active area; and a third doped region is formed at one of two ends of the second active area and a fourth doped region is formed at the other of the two ends of the second active area. A gate structure is formed above the second doped region and the third doped region, in which the gate structure is connected to the second doped region and the third doped region. Thus, the gate structure is arranged on the second doped region in the first active area and the third doped region in the second active area, so that the states of two active areas can be controlled by one gate structure. Accordingly, the device integration is improved, and the electrical property of a semiconductor is improved.

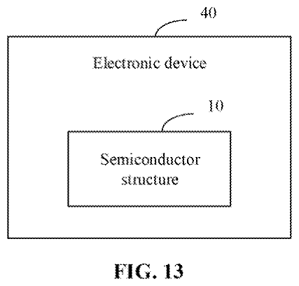

Another embodiment of the disclosure refers to FIG. 13, which illustrates a schematic diagram of an electronic device 40 according to an embodiment of the present disclosure. As shown in FIG. 13, the electronic device 40 includes the aforementioned semiconductor structure 10.

Since the electronic device 40 includes the semiconductor structure 10, and the gate structure in the semiconductor structure is arranged on the second doped region in the first active area and the third doped region in the second active area, the states of two active areas can be controlled by one gate structure. Accordingly, the device integration is improved, and the electrical property of the semiconductor is improved.

The embodiments of the disclosure provide a semiconductor structure and a method for preparing the semiconductor structure. The semiconductor structure includes a substrate. A first active area, a second active area and an isolation structure are arranged on the substrate. Herein, the first active area and the second active area are isolated from one another by the isolation structure. The first active area includes a first doped region and a second doped region. The second active area includes a third doped region and a fourth doped region. The semiconductor structure further includes a gate structure. The gate structure is arranged above the second doped region and the third doped region, and the gate structure is connected to the second doped region and the third doped region. Thus, the semiconductor structure of the embodiments of the disclosure can improve the device integration and improve the electrical property of the semiconductor.

The foregoing descriptions are only preferred embodiments of the disclosure and are not intended to limit the scope of protection of the disclosure.

It is to be noted that terms “include” and “contain” or any other variant thereof is intended to cover nonexclusive inclusions herein, so that a process, method, object or device including a series of elements not only includes those elements but also includes other elements which are not clearly listed or further includes elements intrinsic to the process, the method, the object or the device. Without further restrictions, the element defined by the statement “including a . . . ” does not exclude the existence of another same element in the process, method, article or device including the element.

The sequence numbers of the embodiments of the disclosure are adopted not to represent superiority-inferiority of the embodiments but only for description.

The methods disclosed in several method embodiments provided in the present disclosure may be arbitrarily combined with each other without conflict to obtain a new method embodiment.

The characteristics disclosed in a plurality of product embodiments provided in the present disclosure may be arbitrarily combined with each other without conflict to obtain a new product embodiment.

The characteristics disclosed in the several method or device embodiments provided in the present disclosure may be arbitrarily combined with each other without conflict to obtain a new method embodiment or device embodiment.

The above is only the specific implementation mode of the present disclosure and not intended to limit the scope of protection of the present disclosure. Any variations or replacements apparent to those skilled in the art within the technical scope disclosed by the present disclosure shall fall within the scope of protection of the present disclosure. Therefore, the scope of protection of the present disclosure shall be subject to the scope of protection of the claims.

What is claimed is:

1. A semiconductor structure, comprising:
a substrate, wherein a first active area, a second active area and an isolation structure are arranged on the substrate, and the first active area and the second active area are isolated from one another by the isolation structure,
wherein the first active area comprises a first doped region and a second doped region, and the second active area comprises a third doped region and a fourth doped region,
wherein the semiconductor structure further comprises a gate structure, the gate structure is arranged above the second doped region and the third doped region, and the gate structure is connected to the second doped region and the third doped region.

2. The semiconductor structure of claim 1, wherein a doping type of the second doped region is the same as a doping type of the third doped region.

3. The semiconductor structure of claim 2, wherein a doping type of the first doped region is contrary to a doping type of the fourth doped region.

4. The semiconductor structure of claim 3, wherein the doping type of the third doped region is the same as the doping type of the fourth doped region, and a doping concentration of the third doped region is different from a doping concentration of the fourth doped region.

5. The semiconductor structure of claim 4, wherein the doping type of the first doped region is N-type doping, each of the doping type of the second doped region, the doping type of the third doped region and the doping type of the fourth doped region is P-type doping, and the doping concentration of the fourth doped region is higher than the doping concentration of the third doped region.

6. The semiconductor structure of claim 1, wherein the first active area and/or the second active area comprises at least one fin structure.

7. The semiconductor structure of claim 6, wherein the second doped region is located at an end of the first active area close to the second active area, and the third doped region is located at an end of the second active area close to the first active area.

8. The semiconductor structure of claim 7, wherein the second doped region comprises a first connection region, and the first connection region connects at least two fin structures of the first active area together.

9. The semiconductor structure of claim 7, wherein the third doped region comprises a second connection region, and the second connection region connects at least two fin structures of the second active area together.

10. The semiconductor structure of claim 8, wherein the third doped region comprises a second connection region, and the second connection region connects at least two fin structures of the second active area together.

11. A method for preparing a semiconductor structure, comprising:
providing a substrate;
forming a first active area, a second active area and an isolation structure on the substrate, wherein the first active area and the second active area are isolated from one another by the isolation structure;
forming a first doped region at one of two ends of the first active area and forming a second doped region at the other of the two ends of the first active area; forming a third doped region at one of two ends of the second active area and forming a fourth doped region at the other of the two ends of the second active area; and
forming a gate structure above the second doped region and the third doped region, wherein the gate structure is connected to the second doped region and the third doped region.

12. The method for preparing the semiconductor structure of claim 11, wherein forming the first active area, the second active area and the isolation structure on the substrate comprises:
forming a covering layer on the substrate, and forming a patterned mask on the covering layer;
performing pattern transfer processing on the substrate through the patterned mask, and removing the patterned mask and the covering layer to obtain the first active area and the second active area; and
filling an insulating material between the first active area and the second active area to obtain the isolation structure.

13. The method for preparing the semiconductor structure of claim 12, wherein forming the patterned mask on the covering layer comprises:
forming an initial pattern on the covering layer;
performing cutting processing on the initial pattern to obtain a first pattern and a second pattern; and
depositing a first dielectric layer on a sidewall of the first pattern and a sidewall of the second pattern, and removing the first pattern and the second pattern, wherein the first dielectric layer is retained to obtain the patterned mask.

14. The method for preparing the semiconductor structure of claim 11, further comprising:
forming a first mask layer on the first active area and the second active area, wherein the first mask layer covers part of the first active area and part of the second active area, and the first mask layer exposes an end of the first active area away from the second active area and an end of the second active area away from the first active area;
performing a first doping process on the end of the first active area away from the second active area to obtain the first doped region; performing a second doping process on the end of the second active area away from the first active area to obtain the fourth doped region;
removing the first mask layer and forming a second mask layer, wherein the second mask layer covers the first doped region and the fourth doped region, and the second mask layer is absent on an end of the first active area close to the second active area and an end of the second active area close to the first active area;
performing a third doping process on the end of the first active area close to the second active area and the end of the second active area close to the first active area to obtain the second doped region and the third doped region; and
removing the second mask layer, and forming the gate structure on the second doped region and the third doped region.

15. The method for preparing the semiconductor structure of claim 11, further comprising:
forming a third mask layer on the first active area and the second active area, wherein the third mask layer covers part of the first active area and part of the second active area, and the third mask layer exposes an end of the first active area close to the second active area and an end of the second active area close to the first active area;
performing a third doping process on the end of the first active area close to the second active area and the end of the second active area close to the first active area to obtain the second doped region and the third doped region;
removing the third mask layer, and forming the gate structure on the second doped region and the third doped region; and
performing a first doping process on an end of the first active area away from the second active area to obtain the first doped region; and performing a second doping process on an end of the second active area away from the first active area to obtain the fourth doped region.

16. The method for preparing the semiconductor structure of claim 14, wherein a doping type of the first doping process is contrary to a doping type of the third doping process, a doping type of the second doping process is the same as the doping type of the third doping process, and a doping concentration of the second doping process is different from a doping concentration of the third doping process.

17. The method for preparing the semiconductor structure of claim 15, wherein a doping type of the first doping process is contrary to a doping type of the third doping process, a doping type of the second doping process is the same as the doping type of the third doping process, and a doping concentration of the second doping process is different from a doping concentration of the third doping process.

18. The method for preparing the semiconductor structure of claim 16, wherein a doping type of the first doped region is N-type doping, each of a doping type of the second doped region, a doping type of the third doped region and a doping type of the fourth doped region is P-type doping, and a doping concentration of the fourth doped region is higher than a doping concentration of the third doped region.
